(19) United States
(12) Patent Application Publication
(10) Pub. No.: US 2021/0218257 A1
(43) Pub. Date: Jul. 15, 2021

(54) METHOD FOR CHARGING A CELL, AND METHOD AND SYSTEM FOR CHARGING A BATTERY IN FULL LIFE CYCLE INCLUDING PULSE CHARGING AT AN OVERCHARGE VOLTAGE OR AN OVERCHARGE CURRENT

(71) Applicant: CHANGXING TAIHU ELECTRIC CORPORATION, Huzhou (CN)

(72) Inventor: Jianbin Wu, Huzhou (CN)

(21) Appl. No.: 16/854,878

(22) Filed: Apr. 21, 2020

(30) Foreign Application Priority Data
Jan. 9, 2020 (CN) 202010019906.3

(51) Int. Cl. H02J 7/00

(52) U.S. Cl. CPC H02J 7/0071; H02J 7/00302; H02J 7/0048; H02J 7/005; H02J 7/0014; H02J 7/007192; H02J 7/00712

(57) ABSTRACT

A method for charging a battery includes: calculating a charge pulse at a next moment based on real-time data of the battery, and change information of a first charge time t_{c1} and a second charge time t_{c2}, and change information of a first relaxation time tᵣ₁ and a second relaxation time tᵣ₂, so that the battery has a longest time for being at a highest bearable charge voltage/current in a healthy state, until the battery is fully charged. t_{c1}/tᵣ₂ is a longest time within which the cell is at an overcharge voltage/current but no irreversible damage has been formed during a charge, and tᵣ₁/tᵣ₂ is a time within which the cell recovers from an overcharged state to a normal state within t_{c1}/t_{c2}. Based on the present invention, low-cost and well balanced fast charging is implemented when a requirement of reducing consistency between cells is reduced.

### CROSS REFERENCE TO RELATED APPLICATIONS

The present application claims the benefit of Chinese Patent Application No. 202010019906.3 filed on Jan. 9, 2020, the contents of which are incorporated herein by reference in their entirety.

### TECHNICAL FIELD

The present invention relates to the field of battery management technologies, and in particular, to a method for charging a cell, and a method and system for charging a battery in a full life cycle.

### BACKGROUND

Electrochemical energy storage has many advantages, such as a short construction cycle, a short cycle of return on investment, a low environmental requirement, distributed construction, and being suitable for storage of distributed renewable energy, and therefore, is one of important energy storage technologies of an energy internet. How to develop a battery system with high safety, good economy, environmental protection and good replicability is a core problem of distributed energy storage.

A charge technology is one of keys to healthy and safe use of a battery system. Improper charge methods greatly shorten a battery life and even cause serious safety hazards. Spontaneous combustion of lithium-battery electric vehicles and deflagration accidents in energy storage power stations that are frequently occurred recently are all related to methods of improperly charging batteries. For lead-acid batteries, unscientific charge methods can directly lead to battery sulfation or bulging, thereby severely shortening a battery life. A large battery system is generally formed by connecting a plurality of cells serially and in parallel. Although consistency between new cells can be guaranteed when they are grouped, as a battery ages, the consistency deteriorates. In this way, some cells are inevitably overcharged in a charge process, thereby causing the battery system to fail. For this reason, a charge method that is used to effectively delay or control a failure of the battery system is of great significance.

With widespread application of electric systems, fast charging will be one of necessary performance of the battery system, such as ultra-fast charging of an electric vehicle, frequency and peak modulation of a power grid system, and fast charging of an AGV system, and directly affects efficiency of the system. How to balance a charging speed and health performance of a battery is a problem that a charge system definitely faces. For this reason, it is necessary to propose a policy for controlling and managing a battery system in a full life cycle based on a distinctive life characteristic of an electrochemical product.

A current charge system and algorithm are not determined based on a specific state of a charged battery, but are preset based on experience. However, battery management is performed based on the specific status of the charged battery. It can be seen that battery management and charging are usually processed separately, and the two are not closely related. For a system formed by a plurality of serially connected cells, in order to prevent an individual cell from being overcharged, an external intervention method is usually used to prevent overcharging. FIG. 1 shows a passive battery management system that consumes overcharge electricity of a single cell by externally connecting to an impedance load. An advantage of this method is simpleness. A disadvantage is that due to power consumption, a balancing capability cannot be excessively strong. For most passive management systems, a balanced current is generally 100 mA to 200 mA that can be ignored for a charge system whose charge current is 10 A to 100 A. Therefore, for the passive battery management system, a cell generally has a high consistency requirement; otherwise, the passive battery management system cannot be applied. FIG. 2 shows an active battery management system. This system ensures that each cell is not overcharged in a charge process by coordinating energy conversion between cells. In consideration of power consumption and costs, a traditional active battery management system generally has a balanced current of about 5 A. Therefore, the traditional active battery management system has a limited balancing capability, and has a high requirement on cells in groups of a battery. In addition, a balancing method of the active battery management system is not closely related to a charge algorithm. An active balancing algorithm is controlled by a model, and has relatively weak dependence on historical data.

It can be seen that in the charge process, a relatively weak cell balancing capability of the existing battery management system makes a battery system significantly increase a cell consistency requirement. This greatly increases costs. In addition, as a charge speed is increased, a charge current becomes large, and balance between cells becomes impossible, thereby causing some cells to be overcharged and accelerating aging of the battery. Seriously, thermal runaway of the battery and safety accidents are further caused.

The application CN201410221990.1 for patent for invention discloses a battery management system and a method for driving the battery management system. The method specifically includes: A primary BMS controls, by using battery status information, a battery unit included in a battery pack, to perform a battery unit balancing operation; the main BMS may output a battery unit balancing signal to each secondary BMS. Then the secondary BMS may perform a battery unit balancing operation by using a passive battery unit balancing method. In the method, electricity of a battery unit in a relatively high state of charge (SOC) is discharged by using a balancing resistor (in other words, a resistor). The secondary BMS may further perform a battery unit balancing operation by using an active battery unit balancing method. In the method, electricity of a battery unit in a relatively high SOC is supplied to a battery unit in a relatively low SOC. Although a balancing operation can be implemented based on this application, there are technical problems claimed in the prior art.

### SUMMARY

For a problem existing in the prior art, the present invention provides a method for charging a cell, and a method and system for charging a battery in a full life cycle.

The present invention is implemented based on the following technical solutions:

The present invention provides a method for charging a cell, including:

if a charge current is controlled within in a safety range, and a second charge time t_{c2} is not less than a first charge time t_{c1}, charging the cell for a time that does not exceed the first charge time t_{c1}; and

if a charge voltage is controlled within in a safety range, and the first charge time t_{c1} is not less than the second charge time t_{c2}, charging the cell for a time that does not exceed the second charge time t_{c2}, where

the first charge time is a longest time within which the cell is at an overcharge voltage but no irreversible damage has been formed during a charge; the second charge time is a longest time within which the cell is at an overcharge current but no irreversible damage has been formed during a charge.

The present invention provides an overcharge method within a safety range, to implement an efficient, safe, and quickly charge. When a cell is to be charged, a charge manner is determined based on t_{c1} and t_{c2}.

Preferably, the first charge time varies with environment temperature, a charge current, a state of charge SOC, and a state of health SOH of a battery.

Preferably, the first charge time is in inverse proportion to the overcharge voltage.

Preferably, the second charge time varies with environment temperature, the charge voltage, a state of charge SOC, and a state of health SOH of a battery.

Preferably, the second charge time is in reverse proportion to the overcharge current.

Preferably, the method further includes: pulsively charging the cell for the time that does not exceed the first charge time t_{c1} or the second charge time t_{c2}.

Preferably, when the cell is charged for the time that does not exceed the first charge time t_{c1}, the cell recovers from an overcharged state to a normal state within a time not less than a first relaxation time tᵣ₁, the first relaxation time is a time within which the cell recovers from an overcharged state to a normal state within the first charge time; when the cell is charged for the time that does not exceed the second charge time t_{c2}, the cell recovers from an overcharged state to a normal state within a time not less than a second relaxation time tᵣ₂, the second relaxation time is a time within which the cell recovers from an overcharged state to a normal state within the second charge time.

A method for charging a battery in a full life cycle is provided, including:

monitoring real-time data of the battery charged based on a charge pulse at a current moment;

calculating a charge pulse at a next moment based on the real-time data of the battery, change information of a first charge time t_{c1} and a first relaxation time tᵣ₁, and change information of a second charge time t_{c2} and a second relaxation time tᵣ₂, so that the battery has a longest time for being at a highest bearable charge voltage or a highest charge current in a healthy state; and

charging the battery by using the calculated charge pulse, where the foregoing process is repeated all through before the battery is fully charged, where

the real-time data of the battery includes voltage, current, and temperature data of the battery;

the first charge time is a longest time within which the cell is at an overcharge voltage but no irreversible damage has been formed during a charge; the first charge time varies with environment temperature, a charge current, a state of charge SOC, and a state of health SOH of the battery; the first relaxation time is a time within which the cell recovers from an overcharged state to a normal state within the first charge time;

the second charge time is a longest time within which the cell is at an overcharge current but no irreversible damage has been formed during a charge; the second charge time varies with environment temperature, a charge voltage, a state of charge SOC, and a state of health SOH of the battery; the second relaxation time is a time within which the cell recovers from an overcharged state to a normal state within the second charge time; and

the charge pulse includes the charge voltage, the first charge time, and the first relaxation time/the second relaxation time; or the charge pulse includes the charge current, the second charge time, and the second relaxation time/the first relaxation time.

The method is applicable to full-life-cycle management of the battery. During use of the battery, a voltage and a current vary with environment temperature, a state of charge SOC of the battery, a state of health SOH of the battery, and the like. Therefore, how to manage the battery in the full life cycle is very important, and charging is appropriately performed based on a real-time change. For example, t_{c1}, t_{c2}, tᵣ₁, and tᵣ₂ are affected due to a change in the environment temperature, the SOC of the battery, or the SOH of the battery. A charge method is precisely adjusted according to this characteristic. When fast charging is ensured, each cell works in the most comfortable area.

Preferably, a principle for selecting the longest time for charging the battery in a healthy state at the highest bearable charge voltage or the highest charge current is:

if a charge current is controlled within in a safety range, and a second charge time t_{c2} is not less than a first charge time t_{c1}, charging a cell for a time that does not exceed the first charge time t_{c1}; and

if the charge voltage is controlled within in a safety range, and the first charge time t_{c1} is not less than the second charge time t_{c2}, charging the cell for a time that does not exceed the second charge time t_{c2}.

Preferably, the step of calculating a charge pulse at a next moment based on the real-time data of the battery, change information of a first charge time t_{c1} and a first relaxation time tᵣ₁, and change information of a second charge time t_{c2} and a second relaxation time tᵣ₂, so that the battery has a longest time for being at a highest bearable charge voltage or a highest charge current in a healthy state includes:

determining a first charge pulse of each cell at a next moment based on the real-time data of the battery and a first curve of a first charge time t_{c1} and a first relaxation time tᵣ₁ of each cell varying with a charge voltage, temperature, an SOC, and an SOH;

determining a second charge pulse of each cell at the next moment based on the real-time data of the battery and a second curve of a second charge time t_{c2} and a second relaxation time tᵣ₂ of each cell varying with a charge current, temperature, an SOC, and an SOH; and

selecting a smallest charge time from the first charge time t_{c1} in the first charge pulses and the second charge time t_{c2} in the second charge pulses of all cells, selecting a largest relaxation time from the first relaxation time tᵣ₁ in the first charge pulses and the second relaxation time tᵣ₂ in the second charge pulses of all the cells, and constituting the charge pulse of the battery at the next moment by using the smallest charge time and the largest relaxation time that are selected.

Preferably, the method of calculating the charge pulse at the next moment is applicable to a battery formed by serially connecting a plurality of cells, or a battery formed by connecting a plurality of cells in parallel, or a battery formed by connecting a plurality of cells serially and in parallel.

Preferably, when the battery includes serially connected cells, the step of calculating a charge pulse at a next moment based on the real-time data of the battery, change information of a first charge time t_{c1} and a first relaxation time tᵣ₁, and change information of a second charge time t_{c2} and a second relaxation time tᵣ₂, so that the battery has a longest time for being at a highest bearable charge voltage or a highest charge current in a healthy state includes:

when none of the serially connected cells are fully charged,

determining a first charge pulse of each cell at a next moment based on the real-time data of the battery and a first curve of a first charge time t_{c1} and a first relaxation time tᵣ₁ of each cell varying with a charge voltage, temperature, an SOC, and an SOH;

determining a second charge pulse of each cell at the next moment based on the real-time data of the battery and a second curve of a second charge time t_{c2} and a second relaxation time tᵣ₂ of each cell varying with a charge current, temperature, an SOC, and an SOH; and selecting a smallest charge time from the first charge time tc1 in the first charge pulses and the second charge time t_{c2} in the second charge pulses of all cells, selecting a largest relaxation time from the first relaxation time tᵣ₁ in the first charge pulses and second relaxation time tᵣ₂ in the second charge pulses of all the cells, and constituting the charge pulse of the battery at the next moment by using the smallest charge time and the largest relaxation time that are selected; and

when at least one of the serially connected cells reaches a fully charged state,

first discharging the cell in a fully charged state;

then determining a first charge pulse of each cell at a next moment based on the real-time data of the battery and a first curve of a first charge time t_{c1} and a first relaxation time tᵣ₁ of each cell varying with a charge voltage, temperature, an SOC, and an SOH;

determining a second charge pulse of each cell at the next moment based on the real-time data of the battery and a second curve of a second charge time t_{c2} and a second relaxation time tᵣ₂ of each cell varying with a charge current, temperature, an SOC, and an SOH; and

selecting a smallest charge time from the first charge time t_{c1} in first charge pulses and the second charge time t_{c2} in the second charge pulses of all cells, selecting a largest relaxation time from the first relaxation time tᵣ₁ in the first charge pulses and the second relaxation time tᵣ₂ in the second charge pulses of all the cells, and constituting the charge pulse of the battery at the next moment by using the smallest charge time and the largest relaxation time that are selected.

Preferably, the manner of discharging the cell in a fully charged state includes:

discharging the fully charged cell to the ground; or

discharging the fully charged cell to a cell that reaches an undercharged state, so that the cell that reaches an undercharged state still does not reach a fully charged state after receiving electricity.

Preferably, the method further includes: correcting the first curve and the second curve of each cell in real time based on the real-time data of the battery, the SOC, and the SOH.

Preferably, the method is applicable to a charge of a chemical battery.

A system for charging a battery in a full life cycle is provided, including a battery module, a detection and protection module, a power supply, a database, and a calculation control module, where the database stores change information of a first charge time t_{c1} and a first relaxation time tᵣ₁ of the battery, and change information of a second charge time t_{c2} and a second relaxation time tᵣ₂; the detection and protection module is configured to detect the battery module in real time; the calculation control module calculates a charge pulse at a next moment based on the real-time data of the battery, the change information of the first charge time t_{c1} and the first relaxation time tᵣ₁, and the change information of the second charge time t_{c2} and the second relaxation time tᵣ₂, so that the battery has a longest time for being at a highest bearable charge voltage or a highest charge current in a healthy state; and the power supply performs charging based on the charge pulse calculated by the calculation control module, until charging is completed;

the real-time data of the battery includes voltage, current, and temperature data of the battery.

the first charge time is a longest time within which a cell is at an overcharge voltage but no irreversible damage has been formed during a charge; the first charge time varies with environment temperature, a charge current, a state of charge SOC, and a state of health SOH of the battery; the first relaxation time is a time within which the cell recovers from an overcharged state to a normal state within the first charge time;

the second charge time is a longest time within which the cell is at an overcharge current but no irreversible damage has been formed during a charge; the second charge time varies with environment temperature, the charge voltage, a state of charge SOC, and a state of health SOH of the battery; the second relaxation time is a time within which the cell recovers from an overcharged state to a normal state within the second charge time; and

the charge pulse includes the charge voltage, the first charge time, and the first relaxation time/the second relaxation time; or the charge pulse includes the charge current, the second charge time, and the second relaxation time/the first relaxation time.

The charge system is implemented based on the foregoing method for charging the battery in a full life cycle, and can perform management in the full life cycle and adjust an appropriate charge manner according to a real-time state of the battery in the cycle. Therefore, the charge system can reduce a requirement on consistency between cells and present a good balancing capability.

Preferably, the calculation control module includes:

a first charge pulse calculation unit, configured to determine a first charge pulse of each cell at a next moment based on the real-time data of the battery and a first curve of a first charge time t_{c1} and a first relaxation time tᵣ₁ of each cell varying with a charge voltage, temperature, an SOC, and an SOH;

a second charge pulse calculation unit, configured to determine a second charge pulse of each cell at the next moment based on the real-time data of the battery and a second curve of a second charge time t_{c2} and a second relaxation time tᵣ₂ of each cell varying with a charge current, temperature, an SOC, and an SOH; and

a battery charge pulse calculation unit, configured to: select a smallest charge time from first charge time t_{c1} in first charge pulses and second charge time t_{c2} in second charge pulses of all cells, select a largest relaxation time from first relaxation time tr1 in the first charge pulses and second relaxation time tᵣ₂ in the second charge pulses of all the cells, and constitute the charge pulse of the battery at the next moment by using the smallest charge time and the largest relaxation time that are selected.

Preferably, the system further includes: a battery energy management module and a switch module that are disposed between the power supply and the battery module; the calculation control module further includes a discharge control unit, configured to: when the battery energy management module detects that at least one of serially connected cells reaches a fully charged state, control the switch module to cut off the power supply and control the cell reaching a fully charged state to perform a discharge operation; and after the discharge is completed, then control the switch module to connect to the power supply for charging, and trigger the first charge pulse calculation unit, the second charge pulse calculation unit, and the battery charge pulse calculation unit to work.

The present invention has the following beneficial effects:

The present invention provides a method for charging a cell, and a method and system for charging a battery in a full life cycle. Battery management and battery charge control are combined, and battery management and charge adaptive regulation are performed in the full life cycle of the battery, so that a battery charge and battery management can be closely related. In addition, big data tracking is performed on behavior of the battery by using a concept of full-life-cycle management. Based on this, the battery charge method and a battery management mode are changed in real time, so that regardless of any charge mode, balance management of the battery can reach an optimized state, thereby greatly improving a price/performance ratio of running of the battery system. In addition, the present invention is applicable to charging of various types of electrochemical batteries, and is also applicable to charging batteries composed of different connection structures of cells. A real-time status of each cell can be effectively monitored while it is ensured that each cell works in a healthy area with good balance, and is charged fastest and the most safely.

### BRIEF DESCRIPTION OF THE DRAWINGS

FIG. 1 is a schematic structural diagram of an existing passive battery management system;

FIG. 2 is a schematic structural diagram of an existing active battery management system;

FIG. 3 is a curve diagram of a relationship between an oxygen recombination current and a float charge voltage;

FIG. 4a is a curve diagram of a relationship between a first charge time t_{c1} and an overcharge voltage;

FIG. 4b is a curve diagram of a relationship between a second charge time t_{c2} and an overcharge current;

FIG. 5a is a schematic diagram of a voltage pulse;

FIG. 5b is a schematic diagram of a current pulse;

FIG. 5c is a schematic diagram of a charge waveform obtained by performing charging in a manner in FIG. 5a;

FIG. 5d is a schematic diagram of a charge waveform obtained by performing charging in a manner in FIG. 5b;

FIG. 6 is a flowchart of a method for charging a battery in a full life cycle according to the present invention;

FIG. 7 is a schematic diagram of a battery formed by a plurality of cells that are serially connected successively;

FIG. 8 is a schematic diagram of a battery formed by a plurality of cells that are connected in parallel to each other;

FIG. 9a is a schematic diagram of a battery formed by a plurality of cells that are connected serially and in parallel, where the battery in the figure is a battery formed by successively and serially connecting a plurality of groups of cells connected in parallel;

FIG. 9b is a schematic diagram of a battery formed by a plurality of cells that are connected serially and in parallel, where the battery in the figure is a battery formed by connecting, in parallel to each other, a plurality of groups of serially connected cells;

FIG. 10 is a schematic diagram of a charge system using a method for charging the battery in a full life cycle according to the present invention;

FIG. 11 is a diagram of an example of a specific implementation of the charge system shown in FIG. 10;

FIG. 12 is a schematic diagram of a working procedure of the system shown in FIG. 10; and

FIG. 13 is a schematic diagram of a specific implementation of a system for charging a battery in a full life cycle according to the present invention.

### DETAILED DESCRIPTION

The following are specific embodiments of the present invention and the technical solutions of the present invention are further described with reference to the accompanying drawings. However, the present invention is not limited to these embodiments.

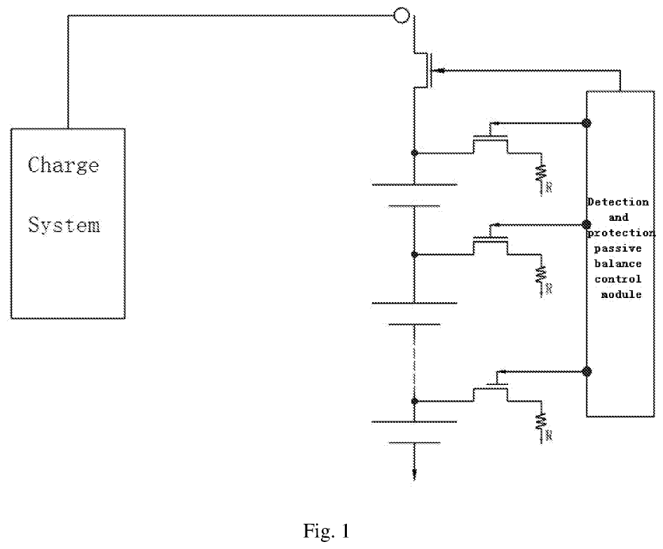

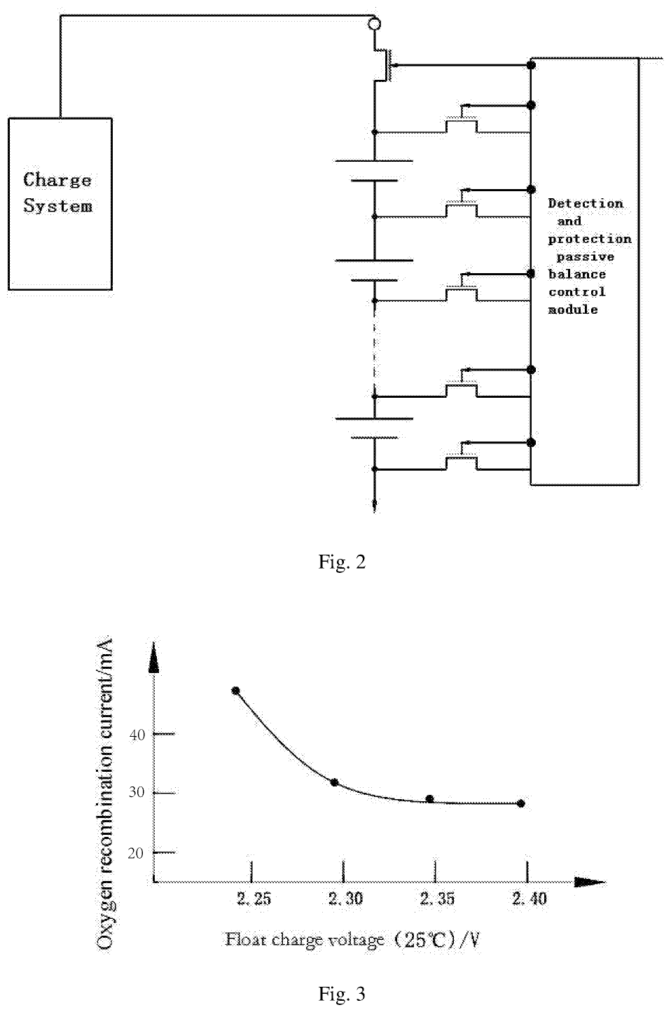

Among existing battery management systems, both an active battery management system (as shown in FIG. 2) and a passive battery management system (as shown in FIG. 1) use an intervention method to prevent a cell from being overcharged. However, in an intervention process, although the passive battery management system consumes overcharge electricity of a single cell by externally connecting to an impedance load, overheating caused by long-term use of the impedance load tends to generate more power consumption. For this reason, the passive battery management system has a limited balancing capability that is not strong. Although the active battery management system can coordinate energy conversion between cells by using a switch matrix, to prevent a cell from being not overcharged, the active battery management system also has problems of large power consumption and a limited balancing capability that is not strong. These problems also require a battery system to have a high requirement on consistency between cells. Each cell varies in a parameter such as internal resistance, a self-discharge rate, an attenuation rate, or polarization. Even if consistency between cells can be met as much as possible during initial use by selecting the cells with relatively good materials, these parameters change over time. As a charge speed increases and a charge current becomes larger, a difference between the cells becomes larger, and it is more difficult to perform balance between the cells, or even the balance cannot be performed. In the end, the cell is unlimitedly overcharged, and problems such as aging and thermal runaway of the battery occur.

Therefore, how to balance the charge speed and health performance of a battery, to fully match and optimize a charge and battery management and improve battery safety is a problem that urgently needs to be resolved for a charge system.

As is well-known, regardless of whether a lithium-ion battery or a lead-acid battery has a certain limit on a charge voltage and a charge current. In addition, such a requirement varies with environment temperature, a state of charge (SOC) of the battery, a state of health (SOH) of the battery, and the like. Within a safety range, the health performance of the battery can be ensured while a cell of the battery is quickly charged.

FIG. 3 shows an example of a water loss caused by a float charge of a valve-regulated sealed lead-acid battery. The water loss is one of main failure modes of such a battery. The battery has the following main problems: a. Oxygen is not 100% recombined at a negative electrode, and there is a surplus; b. Hydrogen evolution may still occur at the end of a charge, and these hydrogens are not combined into water at a positive electrode. Existing hydrogens are not absorbed at the positive electrode and cannot be recombined. Therefore, the hydrogens are aggregated to increase internal pressure of the battery to certain internal pressure. In this way, a one-way valve (a safety valve) is opened and overflowing occurs, causing a water loss. Therefore, the float charge voltage cannot be increased. If the float charge voltage is higher than a normal float charge voltage of 2.25 V/cell, a float charge current is increased, accumulation of surplus gases is also increased, and oxygen recombination at the negative electrode is blocked, thereby reducing an oxygen circulation capability. The oxygen recombination current becomes smaller as the float charge voltage is increased. FIG. 3 describes a maximum oxygen recombination current at the float charge voltage of 2.25 V/cell (in other words, a normal charge voltage). When a voltage is greater than this voltage, in other words, a larger voltage Vₒᵥₑᵣ that exceeds the normal charge voltage, a smaller oxygen recombination current, and a higher accumulated internal pressure lead to an easier water loss. In other words, a larger Vₒᵥₑᵣ leads to a shorter relaxation time within which the battery is at high internal pressure without starting to lose water. As Vₒᵥₑᵣ continues increasing, a response lag time becomes shorter, so that when it is too late for the system to respond, a damage effect is caused to the battery. When Vₒᵥₑᵣ is limited to a safety range to which the system can respond, charging can be speeded up and safety of the battery can be ensured.

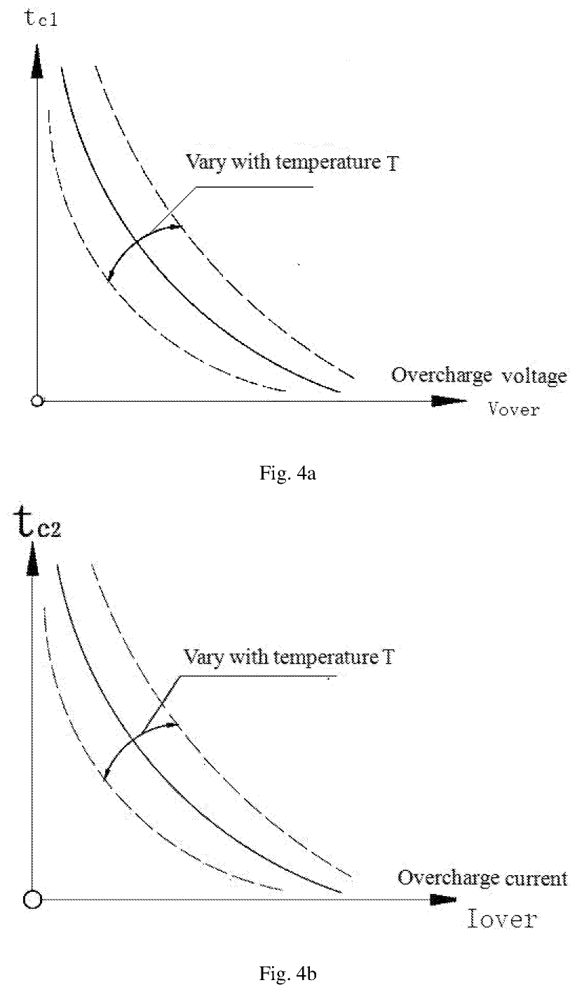

Based on this, as a universal description, the present invention describes a critical time group (a first charge time t_{c1} and a second charge time t_{c2}) to describe a charge state of a cell. The first charge time t_{c1} is a longest time within which the cell is at an overcharge voltage but no irreversible damage has been formed during a charge. The second charge time t_{c2} is a longest time within which the cell is at an overcharge current but no irreversible damage has been formed during a charge. A qualitative relationship between the first charge time t_{c1} and the overcharge voltage (overcharge voltage Vₒᵥₑᵣ=charge voltage−normal charge voltage) is described in FIG. 4a. The first charge time t_{c1} varies with environment temperature, a charge current, a state of charge (SOC), and a state of health (SOH) of the battery. FIG. 4a shows three change curves of the first charge time t_{c1}—the overcharge voltage Vₒᵥₑᵣ that are affected by temperature. When the temperature rises, the overcharge voltage decreases. In each curve, the first charge time t_{c1} is in inverse proportion to the overcharge voltage Vₒᵥₑᵣ. A qualitative relationship between the second charge time t_{c2} and an overcharge current (overcharge current Iₒᵥₑᵣ=charge current−normal charge current) is described in FIG. 4b. The second charge time t_{c2} varies with environment temperature, a charge voltage, a state of charge (SOC), and a state of health (SOH) of the battery. FIG. 4b shows three change curves of the second charge time t_{c2}—the overcharge current Iₒᵥₑᵣ that are affected by the temperature. When the temperature rises, the overcharge current decreases. In each curve, the second charge time t_{c2} is in reverse proportion to the overcharge current Iₒᵥₑᵣ.

With reference to an example in FIG. 3, a larger overcharge voltage Vₒᵥₑᵣ leads to a shorter response lag time within which the battery is at a high internal pressure without starting to lose water, in other words, a shorter first charge time t_{c1}. The trend is basically the same as that of FIG. 4a. In general, as Vₒᵥₑᵣ increases, the first charge time t_{c1} is shortened. If the first charge time t_{c1} is too short for the system to respond in time, a damage effect is caused to the battery. The overcharge voltage Vₒᵥₑᵣ at this time is defined as a maximum allowable overcharge voltage. For lithium batteries, as an overcharge causes deflagration, the maximum overcharge voltage is limited within a safety range as much as possible. Due to high complexity of dependence of the first charge time t_{c1} on the state of the battery and an environment, there is an uncertainty in precisely looking for the first charge time t_{c1} and generating a pulse. Therefore, the first charge time t_{c1} taken without affecting a charge speed is slightly low.

To sum up, when a cell is to be charged, a charge manner may be determined based on the first charge time t_{c1} and the second charge time t_{c2}. Therefore, the present invention provides a method for charging a cell, including:

if a charge current is controlled within in a safety range, and a second charge time t_{c2} is not less than a first charge time t_{c1}, charging the cell for a time that does not exceed the first charge time t_{c1}; and

if the charge voltage is controlled within in a safety range, and the first charge time t_{c1} is not less than the second charge time t_{c2}, charging the cell for a time that does not exceed the second charge time t_{c2}.

When a proper charge method is selected in the foregoing manners, environmentally-adjusted pulsive charging used in the present invention is the most natural charge method. For example, when a voltage pulse is used for charging, the charge pulse includes the charge voltage and t_{c1}. For another example, when a current pulse is used for charging, the charge pulse includes the charge current and t_{c2}. After charging is completed, a next charge is performed after a period of time. A water loss caused by a float charge of a valve-regulated sealed lead-acid battery is used as an example. When a voltage returns to a normal state after overvoltage charging is performed for the first charge time t_{c1}, it takes time for existing hydrogens to recombine at a positive electrode. Although air pressure in the battery no longer increases, a period of time is required for the battery to return to a state before an overcharge state. This period of time is a first relaxation time tᵣ₁. In some cases, the first charge time tᵣ₁ may be very long, thereby causing two charge pulses to be far apart. This affects a charge speed. If a pulse interval is too short, hydrogens are not completely recombined after each pulse, and accumulation occurs after each pulse, until pressure is too high and water is lost. Therefore, how to optimize the first charge time t_{c1} and the first relaxation time tᵣ₁ is the key to healthy operation of the battery without affecting the charge speed. This period of time can be infinite. However, in consideration of charge efficiency, as long as thermodynamic equilibrium is reached, a next charge can be performed. Therefore, a time (or referred to as a relaxation time) required to perform recovery from the overcharged state to the normal state is described: the first relaxation time tᵣ₁ and the second relaxation time tᵣ₂, to describe a waiting time required between an end of this charge and a start of a next charge. In other words, when the cell is charged for the time that does not exceed the first charge time t_{c1}, the cell recovers from an overcharged state to a normal state within a time not less than a first relaxation time tᵣ₁; when the cell is charged for the time that does not exceed the second charge time t_{c2}, the cell recovers from an overcharged state to a normal state within a time not less than a second relaxation time tᵣ₂.

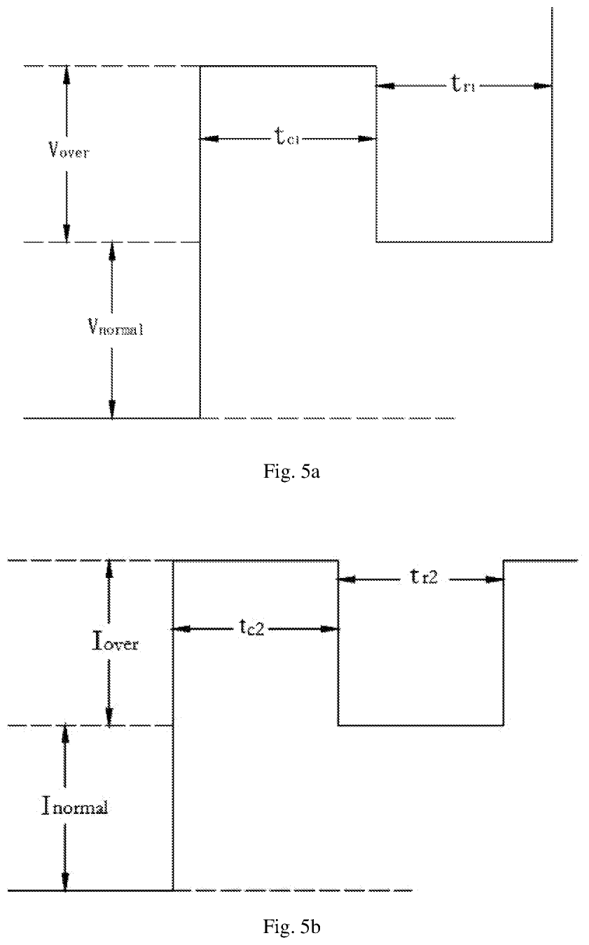

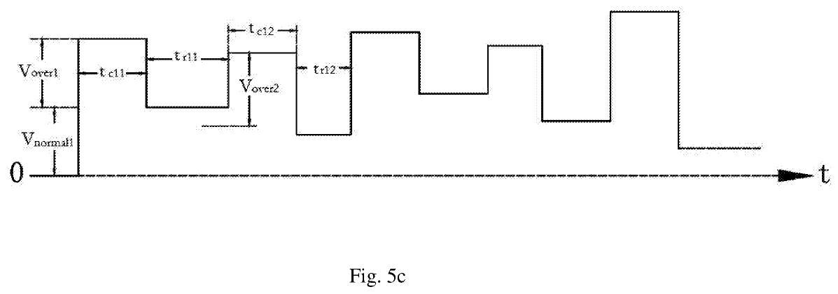

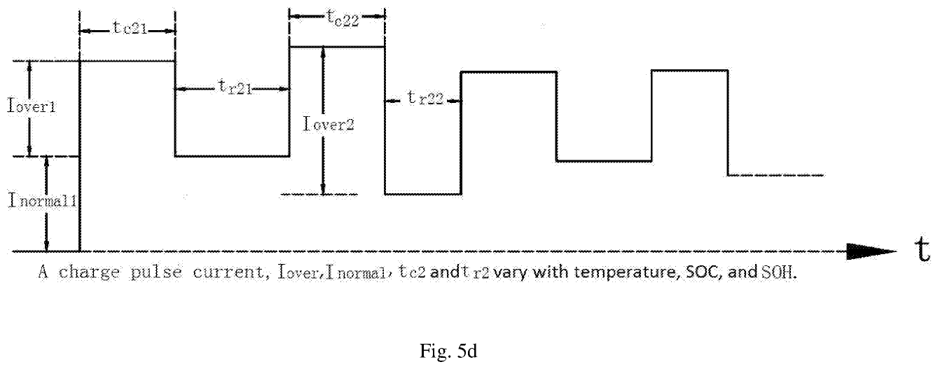

The first charge time t_{c1}, the first relaxation time tᵣ₁, and the charge voltage (Vₙₒᵣₘₐₗ+Vₒᵥₑᵣ) constitute a voltage charge pulse (as shown in FIG. 5a). When it is determined that charging is to be performed in this manner, a charge waveform is shown in FIG. 5c. The charge voltages Vₒᵥₑᵣ and Vₙₒᵣₘₐₗ, t_{c1}, and tᵣ₁ in the charge pulse all change with temperature, an SOC, and an SOH. The second charge time t_{c2}, the second relaxation time tᵣ₂, and the charge current (Iₙₒᵣₘₐₗ+Iₒᵥₑᵣ) constitute a current charge pulse (as shown in FIG. 5b). When it is determined that charging is to be performed in this manner, a charge waveform is shown in FIG. 5d. The charge currents Iₒᵥₑᵣ and Iₙₒᵣₘₐₗ, t_{c2}, and tᵣ₂ that are in the charge pulse all change with the temperature, the SOC, and the SOH.

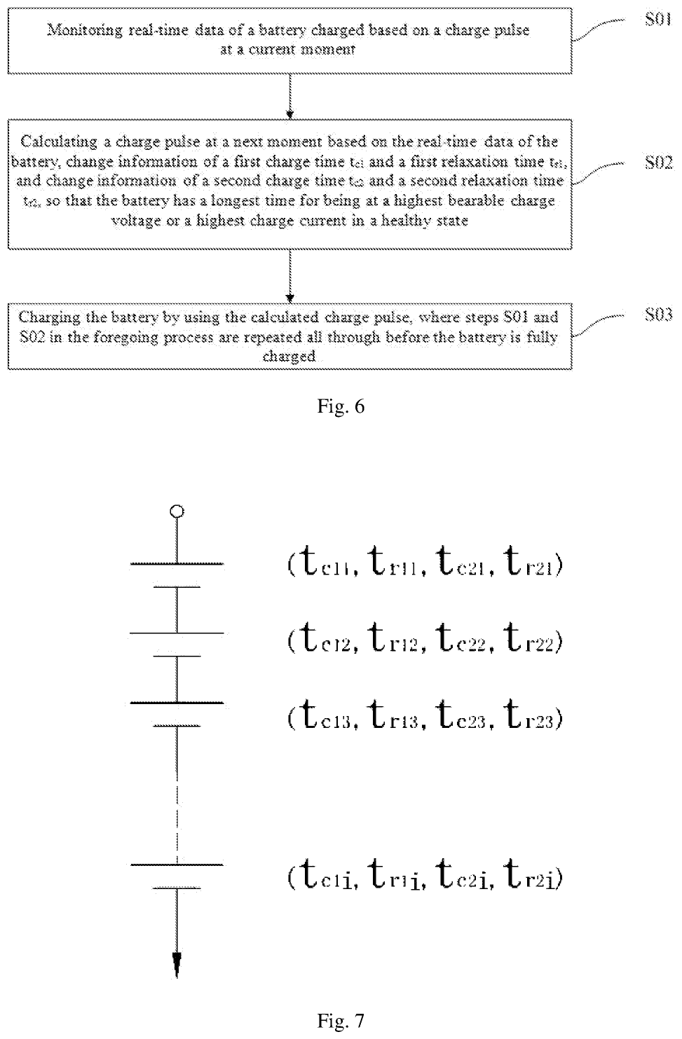

Based on the above charge method, when there is information that (the first charge time t_{c1}, the first relaxation time tᵣ₁), (the second charge time t_{c2}, the second relaxation time tᵣ₂) vary with the environment temperature, the SOC of the battery, and the SOH of the battery, the cell can be controlled to always work in a most comfortable zone. Therefore, as shown in FIG. 6, the present invention provides a method for charging a battery in a full life cycle, including the following steps.

Step 01. Monitoring real-time data of the battery charged based on a charge pulse at a current moment.

Step 02. Calculating a charge pulse at a next moment based on the real-time data of the battery, change information of a first charge time tc1 and a first relaxation time tᵣ₁, and change information of a second charge time t_{c2} and a second relaxation time tᵣ₂, so that the battery has a longest time for being at a highest bearable charge voltage or a highest charge current in a healthy state.

Step 03. Charging the battery by using the calculated charge pulse, where steps SOI and S02 in the foregoing process is repeated all through before the battery is fully charged.

The real-time data of the battery includes voltage, current, and temperature data of the battery. A state of the cell of the battery can be determined based on the real-time data. When step S02 is performed, the charge pulse at the next moment may be calculated and determined by comparing the real-time data of battery and the change information.

In step S02, the first charge time t_{c1}, the first relaxation time tᵣ₁ varies with the overcharge voltage Vₒᵥₑᵣ, the overcharge current Iₒᵥₑᵣ, the temperature, the SOC, and the SOH. Therefore, the change information is recorded by using a curve of the first charge time t_{c1}—the overcharge voltage Vₒᵥₑᵣ, a curve of the first relaxation time tᵣ₁—the overcharge voltage Vₒᵥₑᵣ (referring to a trend of the curve of the first charge time t_{c1}—the overcharge voltage Vₒᵥₑᵣ), a curve of the second charge time t_{c2}—the overcharge current Iₒᵥₑᵣ, and a curve of the second relaxation time tᵣ₂—the overcharge current Iₒᵥₑᵣ (referring to a trend of the curve of the first charge time t_{c1}—the overcharge voltage Vₒᵥₑᵣ). The foregoing curve is initially formed based on initial data provided by a battery manufacturer, and is subsequently corrected in real time based on historical data during use, such as data of temperature, an SOH, an SOC, a current, and a voltage. For this reason, when the real-time data of the battery is compared with the change information, a corresponding appropriate charge pulse is obtained with reference to a curve for a next charge.

A principle for selecting the longest time for charging the battery in a healthy state at the highest bearable charge voltage or the highest charge current is: if a charge current is controlled within in a safety range, and the second charge time t_{c2} is not less than the first charge time tc1, charging the cell for a time that does not exceed the first charge time t_{c1}; and if a charge voltage is controlled within in a safety range, and the first charge time t_{c1} is not less than the second charge time t_{c2}, charging the cell for a time that does not exceed the second charge time t_{c2}. For this reason, based on the above principle, in a process of charging the battery, charging may be performed by using a voltage pulse or a current pulse throughout the charge process, or through a combination of a voltage pulse and a current pulse.

This method is applicable to various types of electrochemical batteries, such as a lithium battery, a lead-acid battery, and a super capacitor. The battery used in the specification may be a battery with a single cell or a battery formed by a plurality of cells.

When charge management is performed on the battery with a single cell, the real-time data of the discharged battery is first monitored based on the charge pulse at the current moment. The state of charge SOC and the state of health SOH of the battery are determined based on the monitored real-time data of the battery including temperature, current, and voltage data. Then the charge pulse at the next moment is determined by comparing the real-time data of the battery with the change information of the first charge time t_{c1} and the first relaxation time tᵣ₁ and the change information of the second charge time t_{c2} and the second relaxation time tᵣ₂. When the charge pulse at the next moment is determined, whether the voltage pulse or the current pulse is used for charging may be determined based on whether the charge current or the charge voltage falls within a safety range, and a value relationship between the first charge time and the second charge time. A proper charge manner is selected at each moment based on real-time data of the battery. The charge pulse includes the charge voltage, the first charge time, and the first relaxation time; or the charge pulse includes the charge current, the second charge time, and the second relaxation time. Next the battery is charged by using the calculated charge pulse, where the monitoring and calculation process is continued before the battery is fully charged.

When charging management is performed on the battery with a plurality of cells, there are various forms of a structure of the battery formed by the plurality of cells, such as a battery formed by a plurality of cells that are serially connected successively, a battery formed by a plurality of cells that are connected in parallel to each other, a battery formed by successively and serially connecting a plurality of groups of cells connected in parallel, a battery formed by connecting, in parallel to each other, a plurality of groups of serially connected cells. The battery is not limited to the foregoing structure, and may be of any battery structure conforming to a use requirement. Based on management performed on the battery with a plurality of cells, the step of calculating the charge pulse is further detailed as follows:

(a) determining a first charge pulse of each cell at a next moment based on the real-time data of the battery and a first curve of a first charge time t_{c1} and a first relaxation time tᵣ₁ of each cell varying with a charge voltage, temperature, an SOC, and an SOH, where the first curve includes the curve of the first charge time t_{c1}—the over-charge voltage Vₒᵥₑᵣ and the curve of the first relaxation time tᵣ₁—the over-charge voltage Vₒᵥₑᵣ;

(b) determining a second charge pulse of each cell at the next moment based on the real-time data of the battery and a second curve of a second charge time t_{c2} and a second relaxation time tᵣ₂ of each cell varying with a charge current, temperature, an SOC, and an SOH, where the second curve includes the curve of the second charge time t_{c2}—the overcharge current lover and the curve of the second relaxation time tᵣ₂—the overcharge current lover; and

(c) selecting a smallest charge time from first charge time t_{c1} in first charge pulses and second charge time t_{c2} in second charge pulses of all cells, selecting a largest relaxation time from first relaxation time tᵣ₁ in the first charge pulses and second relaxation time tᵣ₂ in the second charge pulses of all the cells, and constituting the charge pulse of the battery at the next moment by using the smallest charge time and the largest relaxation time that are selected.

The battery formed by the plurality of serially connected cells shown in FIG. 7 is used as an example. The real-time data of the battery includes temperature 1, a current 1, a voltage 1, an SOC 1, and an SOH 1 of a cell 1; temperature 2, a current 2, a voltage 2, an SOC 2, and an SOH 2 of a cell 2; temperature 3, a current 3, a voltage 3, an SOC 3, and an SOH 3 of a cell 3 . . . ; temperature n, a current n, a voltage n, an SOC n, and an SOH n of a cell n. Each cell includes parameters of the first charge time t_{c1}, a first relaxation time tᵣ, a second charge time t_{c2}, and a second relaxation time tᵣ₂ (referring to FIG. 7). Steps (a) and (b) are calculated in no particular order, and are mainly used to respectively calculate the charge pulses used in a voltage pulse charge manner and a current pulse charge manner. Then an actually required battery charge pulse at the next moment is determined according to step (c) based on principles of Min{t_{c1i}, t_{c2i}} and Max{tᵣₗᵢ tᵣ₂ᵢ}. Due to extension of an aging characteristic of the serially connected cells during normal operation and a difference between self-discharge rates of batteries, battery charges are not balanced. For this reason, in consideration of a difference of each cell and healthy use of the cell, the entire battery is charged by using a smallest charge time value among the serially connected cells, and recovery is performed by using a maximum relaxation time value among the serially connected cells. A most appropriate value is re-determined as a next charge pulse according to real-time data of all the cells of the battery at each moment. In this way, this can reduce a requirement for consistency among the cells in the battery structure with the plurality of serially connected cells, resolve a problem of charge balance of the battery, and make full use of a battery capacity. The charge pulse includes the charge voltage, the first charge time, and the first relaxation time/the second relaxation time; or the charge pulse includes the charge current, the second charge time, and the second relaxation time/the first relaxation time.

When the battery formed by the plurality of cells serially connected successively is undercharged, charging is performed according to steps (a) to (c). Once a cell reaches a fully charged state, if charging is still performed based on the foregoing process, for the fully charged cell, a charge pulse cannot be charged into the cell. The fully charged cell is in a charge state all through, temperature increases, internal resistance of the cell increases, and the cell gradually ages and is even damaged. Therefore, charging needs to be properly adjusted. When at least one of the serially connected cells reaches a fully charged state,

the cell in a fully charged state is first discharged; then a first charge pulse of each cell at a next moment is determined based on the real-time data of the battery and a first curve of a first charge time t_{c1} and a first relaxation time tᵣ₁ of each cell varying with a charge voltage, temperature, an SOC, and an SOH;

a second charge pulse of each cell at the next moment is determined based on the real-time data of the battery and a second curve of a second charge time t_{c2} and a second relaxation time tᵣ₂ of each cell varying with a charge current, temperature, an SOC, and an SOH; and

a smallest charge time is selected from first charge time t_{c1} in first charge pulses and second charge time t_{c2} in second charge pulses of all cells, a largest relaxation time is selected from first relaxation time tᵣ₁ in the first charge pulses and second relaxation time tᵣ₂ in the second charge pulses of all the cells, and the charge pulse of the battery at the next moment is constituted by using the smallest charge time and largest relaxation time that are selected.

The manner of discharging the cell in a fully charged state includes: discharging the fully charged cell to the ground GND; or discharging the fully charged cell to a cell that reaches an undercharged state, so that the cell that reaches an undercharged state still does not reach a fully charged state after receiving electricity.

When the manner of discharging the ground GND is used, a quantity of discharged electricity may be set as required. For example, based on a next battery close to a fully charged state, a quantity of electricity obtained after the fully charged cell is discharged is equal to a quantity of electricity of the next battery close to a fully charged state; or 10% of a quantity of electricity is discharged; or setting is performed in another manner. However, excessively much or less electricity should not be discharged, to ensure that all the cells can be discharged according to a principle that the cells can be quickly fully charged.

When a manner in which discharging is performed to another undercharged cell, discharging may be performed to one, two, more, or all other undercharged cells. For example, based on a cell having a smallest quantity of electricity, the fully charged cell uses half of a difference between a quantity of electricity of a fully charged cell and the smallest quantity of electricity as a required quantity of electricity for discharging, so that after the discharging, the quantities of electricity of the two cells are basically equal and neither reaches a fully charged state. For another example, based on a cell having a smallest quantity of electricity, the fully charged cell discharges 10% of a quantity of electricity of the fully charged cell to the cell having the smallest quantity of electricity. For another example, the fully charged cell evenly discharges 10% of a quantity of electricity of the fully charged cell to other undercharged cells.

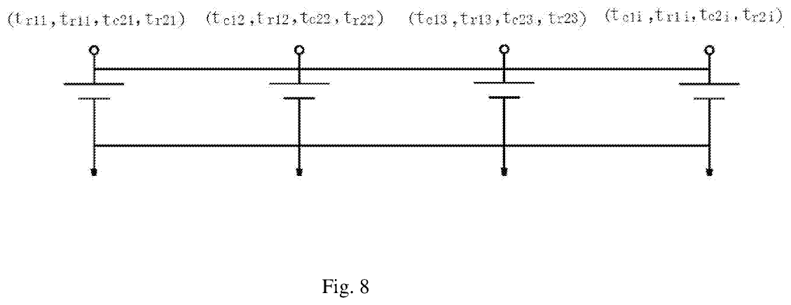

The battery formed by the plurality of cells that are connected in parallel to each other shown in FIG. 8 is used as an example. The real-time data of the battery includes temperature 1, a current 1, a voltage 1, an SOC 1, and an SOH 1 of a cell 1; temperature 2, a current 2, a voltage 2, an SOC 2, and an SOH 2 of a cell 2; temperature 3, a current 3, a voltage 3, an SOC 3, and an SOH 3 of a cell 3 . . . ; temperature n, a current n, a voltage n, an SOC n, and an SOH n of a cell n. Each cell includes parameters of the first charge time t_{c1}, a first relaxation time tᵣ, a second charge time t_{c2}, and a second relaxation time tᵣ₂ (referring to FIG. 8). Steps (a) and (b) are calculated in no particular order, and are mainly used to respectively calculate the charge pulses used in a voltage pulse charge manner and a current pulse charge manner. Then an actually required battery charge pulse at the next moment is determined according to step (c) based on principles of Min{t_{c1l}, t_{c2i}} and Max{tᵣ₁ₗ, tᵣ₂ᵢ}. Due to inconsistency among the cells, currents passing through the cells are different at an equal voltage, and a cross current is formed. For this reason, in consideration of a difference of each cell and healthy use of the cell, the entire battery is charged by using a smallest charge time value among the cells connected in parallel, and recovery is performed by using a maximum relaxation time value among the cells connected in parallel. A most appropriate value is re-determined as a next charge pulse according to real-time data of all the cells of the battery at each moment. In this way, this can reduce a requirement for consistency among the cells in the battery structure with the plurality of cells connected in parallel, resolve a problem of charge balance of the battery, and effectively suppress a charge cross current when each cell is discharged. The charge pulse includes the charge voltage, the first charge time, and the first relaxation time/the second relaxation time; or the charge pulse includes the charge current, the second charge time, and the second relaxation time/the first relaxation time.

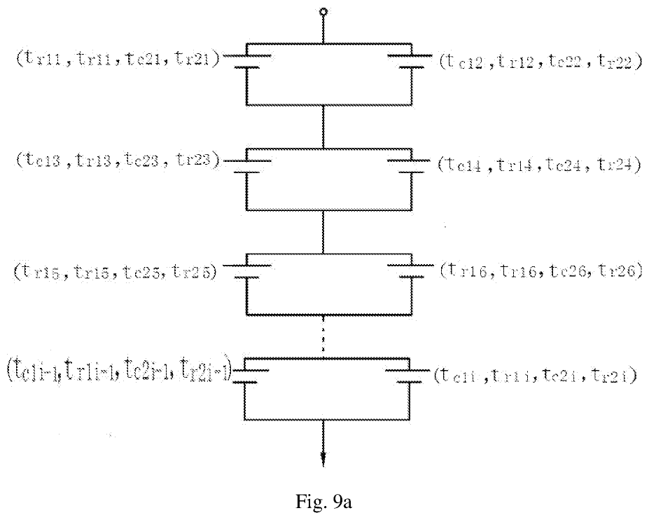

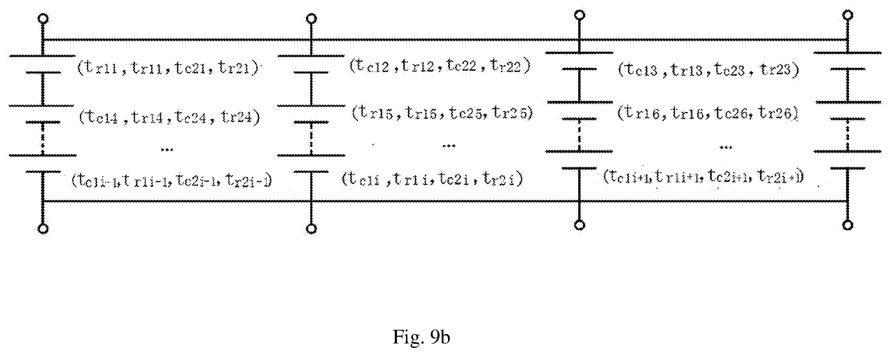

The battery formed by plurality of cells that are connected serially and in parallel shown in FIG. 9a and FIG. 9b is used as an example. The real-time data of the battery includes temperature 1, a current 1, a voltage 1, an SOC 1, and an SOH 1 of a cell 1; temperature 2, a current 2, a voltage 2, an SOC 2, and an SOH 2 of a cell 2; temperature 3, a current 3, a voltage 3, an SOC 3, and an SOH 3 of a cell 3 . . . , temperature n, a current n, a voltage n, an SOC n, and an SOH n of a cell n. Each cell includes parameters of the first charge time t_{c1}, the first relaxation time tᵣ, the second charge time t_{c2}, and the second relaxation time tᵣ₂ (referring to FIG. 9a and FIG. 9b). Steps (a) and (b) are calculated in no particular order, and are mainly used to respectively calculate the charge pulses used in a voltage pulse charge manner and a current pulse charge manner. Then an actually required battery charge pulse at the next moment is determined according to step (c) based on principles of Min{t_{c1i}, t_{c2i}} and Max{tᵣ₁ᵢ, tᵣ₂ᵢ}. For serially connected cells, due to extension of an aging characteristic of the serially connected cells during normal operation and a difference between self-discharge rates of batteries, battery charges are not balanced. For cells connected in parallel, due to inconsistency among the cells, currents passing through the cells are different at an equal voltage, and a cross current is formed. For this reason, in consideration of a difference of each cell and healthy use of the cell, the entire battery is charged by using a smallest charge time value among all the cells, and recovery is performed by using a maximum relaxation time value among all the cells. A most appropriate value is re-determined as a next charge pulse according to real-time data of all the cells of the battery at each moment. In this way, this can reduce a requirement for consistency among the cells in the battery structure with the plurality of cells, resolve a problem of charge balance of the battery, make full use of a battery capacity, and effectively suppress a charge cross current when each cell is discharged. The charge pulse includes the charge voltage, the first charge time, and the first relaxation time/the second relaxation time; or the charge pulse includes the charge current, the second charge time, and the second relaxation time/the first relaxation time.

For serially connected cells, once a cell reaches a fully charged state, if charging is still performed based on the foregoing process, for the fully charged cell, a charge pulse cannot be charged into the cell. The fully charged cell is in a charge state all through, temperature increases, internal resistance of the cell increases, and the cell gradually ages and is even damaged. Therefore, charging needs to be properly adjusted. When at least one of the serially connected cells reaches a fully charged state,

the cell in a fully charged state is first discharged; then a first charge pulse of each cell at a next moment is determined based on the real-time data of the battery and a first curve of a first charge time t_{c1} and a first relaxation time tᵣ₁ of each cell varying with a charge voltage, temperature, an SOC, and an SOH;

(i) a second charge pulse of each cell at the next moment is determined based on the real-time data of the battery and a second curve of a second charge time t_{c2} and a second relaxation time tᵣ₂ of each cell varying with a charge current, temperature, an SOC, and an SOH; and

(ii) a smallest charge time is selected from first charge time t_{c1} in first charge pulses and second charge time t_{c2} in second charge pulses of all cells, a largest relaxation time is selected from first relaxation time tᵣ₁ in the first charge pulses and second relaxation time tᵣ₂ in the second charge pulses of all the cells, and the charge pulse of the battery at the next moment is constituted by using the smallest charge time and largest relaxation time that are selected.

The manner of discharging the cell in a fully charged state includes: discharging the fully charged cell to the ground GND; or discharging the fully charged cell to a cell that reaches an undercharged state, so that the cell that reaches an undercharged state still does not reach a fully charged state after receiving electricity.

When the manner of discharging the ground GND is used, a quantity of discharged electricity may be set as required. For example, based on a next battery close to a fully charged state, a quantity of electricity obtained after the fully charged cell is discharged is equal to a quantity of electricity of the next battery close to a fully charged state; or 10% of a quantity of electricity is discharged; or setting is performed in another manner. However, excessively much or less electricity should not be discharged, to ensure that all the cells can be discharged according to a principle that the cells can be quickly fully charged.

When a manner in which discharging is performed to another undercharged cell, discharging may be performed to one, two, more, or all other undercharged cells. For example, based on a cell having a smallest quantity of electricity, the fully charged cell uses half of a difference between a quantity of electricity of a fully charged cell and the smallest quantity of electricity as a required quantity of electricity for discharging, so that after the discharging, the quantities of electricity of the two cells are basically equal and neither reaches a fully charged state. For another example, based on a cell having a smallest quantity of electricity, the fully charged cell discharges 10% of a quantity of electricity of the fully charged cell to the cell having the smallest quantity of electricity. For another example, the fully charged cell evenly discharges 10% of a quantity of electricity of the fully charged cell to other undercharged cells.

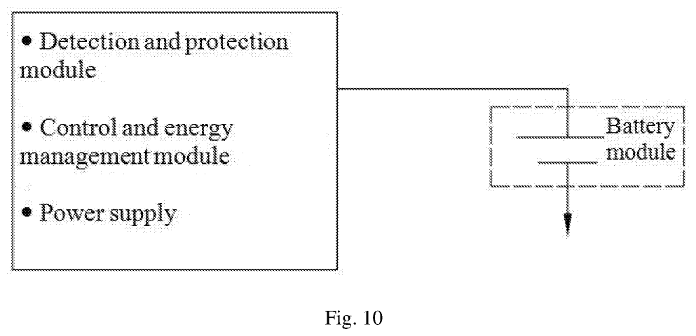

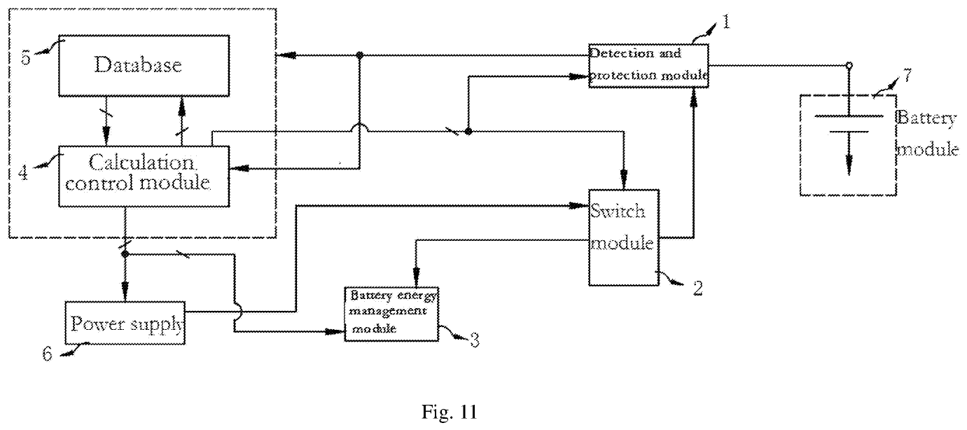

FIG. 10 shows a charge system. The system includes a battery module, a power supply, a detection and protection module, and a control and energy management module. The system can track aging of the battery and a change in (a first charge time t_{c1}, a first relaxation time tᵣ₁), and a change in (a second charge time t_{c2}, a second relaxation time tᵣ₂), and at the same time, can take a protective measure in an extreme case. Based on this, the control and energy management module is configured to generate a charge pulse. The pulse is generated based on measurement of (the first charge time t_{c1}, the first relaxation time tᵣ₁), (the second charge time t_{c2}, the second relaxation time tᵣ₂). The power supply can provide a required voltage, current, and pulse to the battery module based on a requirement.

FIG. 11 shows a specific example of the system shown in FIG. 10. The system includes a battery module 7, a battery energy management module 3, a power supply 6, a database 5, a calculation control module 4, a switch module 2, and a detection and protection module 1. The detection and protection module 1 is configured to: detect real-time data of the battery module, such as a voltage, a current, or temperature, and store the real-time data in the database. When detecting a problem, the detection and protection module 1 further enables a protection function, to immediately protect the battery module. The database 5 stores historical data of the battery and change information of the first charge time t_{c1}, the second charge time t_{c2}, the first relaxation time tᵣ₁, and the second relaxation time tᵣ₂ varying with Vₒᵥₑᵣ, lover, temperature, an SOC, and an SOH, such as a curve of the first charge time t_{c1}—the overcharge voltage Vₒᵥₑᵣ, a curve of the first relaxation time tᵣ₁—the overcharge voltage Vₒᵥₑᵣ, a curve of the second charge time t_{c2}—the overcharge current Iₒᵥₑᵣ, and a curve of the second relaxation time tᵣ₂—the overcharge current Iₒᵥₑᵣ. The database includes a local area database and a cloud database. The calculation control module 4 performs calculation based on the detected battery parameters and database data, to determine a charge pulse, and controls the power supply to output the charge pulse to charge the battery module. After a first charge pulse is ended and before a second charge pulse starts, the calculation control module 4 performs calculation according to the foregoing method by using the measured real-time data and database parameters, so that the battery has a longest time for being at a highest bearable charge voltage or a highest charge current in a healthy state, to determine the second charge pulse. Other cases can be obtained by analogy, until the battery is fully charged.

The battery energy management module 3 is configured to detect a state of the battery. Detection may be performed for a quantity of electricity and a capacity situation of each cell of the battery.

The switch module 2 may include a switch circuit or a switch device, and may perform charge and discharge control and protection control based on instructions of the calculation control module, the battery energy management module, and the detection and protection module.

The detection and protection module 1 includes a detection circuit and a protection circuit. The detection circuit may use a detection circuit that can detect a voltage, a current, and temperature of the battery. The protection circuit may use a commonly used circuit for a battery overcurrent, overheating, and overvoltage protection.

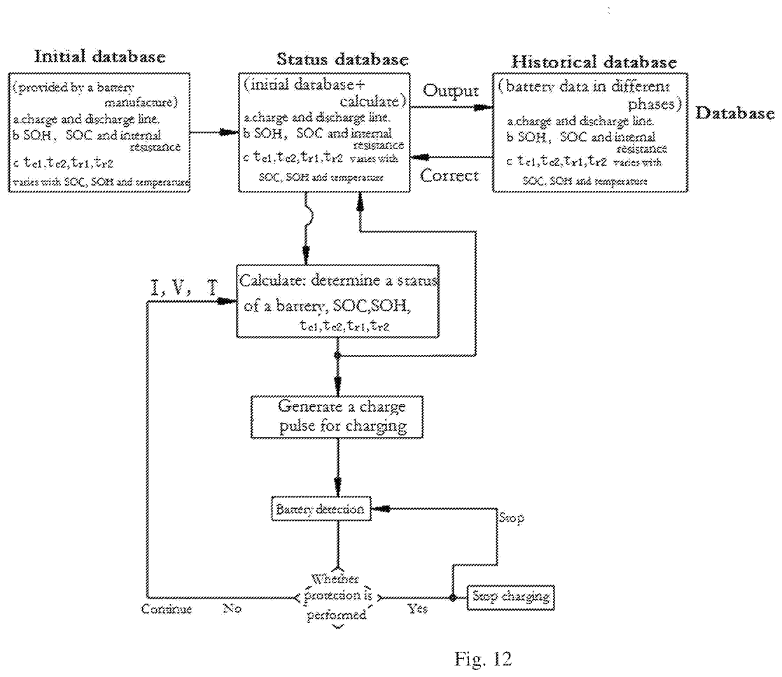

As shown in FIG. 12, the database includes an initial database, a status database, and a historical database. The database stores a charge and discharge curve of the cell, the SOH, the SOC, the internal resistance, the first charge time t_{c1}, the second charge time t_{c2}, and the change information of the first relaxation time tᵣ₁ and the second relaxation time tᵣ varying with Vₒᵥₑᵣ, lover, the temperature, the SOC, and the SOH. At an initial stage, initial data in the initial database is provided by a battery manufacturer, such as the charge and discharge curve, the SOH, the SOC, and the internal resistance, and is determined based on provided initial information, such as the first charge time t_{c1}, the second charge time t_{c2}, and the change information of the first relaxation time tᵣ₁ and the second relaxation time tᵣ₂ varying with Vₒᵥₑᵣ, lover, the temperature, the SOC, and the SOH. In a use phase of the charge system, the status database stores the above information updated in real time. The historical database stores the foregoing battery data in different phases. The status database outputs status data to the historical database. The historical database feeds back information to the status database, information in the database is corrected in each charge cycle, such as the first charge time t_{c1}, the second charge time t_{c2}, and the change information of the first relaxation time tᵣ₁ and the second relaxation time tᵣ₂ varying with Vₒᵥₑᵣ, lover, the temperature, the SOC, and the SOH, so as to ensure that the battery is charged healthily and efficiently.

Depending on the information in the status database, with reference to current, voltage, and temperature data detected by the detection and protection module in real time, the system determines a status of the battery and determines the SOC, the SOH, tᵣ₁, tᵣ₂, t_{c1}, and t_{c2}. A charge pulse suitable for the battery at the next moment is determined by using the method of calculating the charge pulse. When the battery has problems such as overcurrent and overheating, the protection module needs to be activated to control the power supply to stop charging the battery module, for example, using a switch module to disconnect a charge path between the power supply and the battery module. Once the battery returns to a normal state, no protection is required and a charge state is recovered.

Specifically, for a battery formed by a single cell, the calculation control module includes a battery charge pulse calculation unit, configured to determine, based on whether the charge current or the charge voltage falls within a safety range, and a value relationship between the first charge time and the second charge time, whether the voltage pulse or the current pulse is used for charging. A proper charge manner is selected at each moment based on real-time data of the battery.

Specifically, for a battery formed by a plurality of cells, the calculation control module includes a first charge pulse calculation unit, a second charge pulse calculation unit, and a battery charge pulse calculation unit. The first charge pulse calculation unit, configured to determine a first charge pulse of each cell at a next moment based on the real-time data of the battery and a first curve of a first charge time t_{c1} and a first relaxation time tᵣ₁ of each cell varying with a charge voltage, temperature, an SOC, and an SOH. The first curve includes the curve of the first charge time t_{c1}—the over-charge voltage Vₒᵥₑᵣ and the curve of the first relaxation time tᵣ₁—the over-charge voltage Vₒᵥₑᵣ. The second charge pulse calculation unit, configured to determine a second charge pulse of each cell at the next moment based on the real-time data of the battery and a second curve of a second charge time t_{c2} and a second relaxation time tᵣ₂ of each cell varying with a charge current, temperature, an SOC, and an SOH. The second curve includes the curve of the second charge time t_{c2}—the overcharge current lover and the curve of the second relaxation time tᵣ₂—the overcharge current Iₒᵥₑᵣ. The battery charge pulse calculation unit, configured to: select a smallest charge time from first charge time t_{c1} in first charge pulses and second charge time t_{c2} in second charge pulses of all cells, select a largest relaxation time from first relaxation time tᵣ₁ in the first charge pulses and second relaxation time tᵣ₂ in the second charge pulses of all the cells, and constitute the charge pulse of the battery at the next moment by using the smallest charge time and the largest relaxation time that are selected. The calculation control module is applicable to various battery structures, such as a battery formed by a plurality of cells that are serially connected successively, a battery formed by a plurality of cells that are connected in parallel to each other, a battery formed by successively and serially connecting a plurality of groups of cells connected in parallel, a battery formed by connecting, in parallel to each other, a plurality of groups of serially connected cells. The battery is not limited to the foregoing structure, and may be of any battery structure conforming to a use requirement.

The calculation control module further includes a discharge control unit. When a cell is serially connected in the battery, and the battery energy management module detects that a cell reaches a fully charged state, the discharge control unit is activated. Before activation, the switch module disconnects the path used by the power supply to charge the battery module. Then a discharge operation is performed. After discharging is completed, the switch module is closed, and is connected to the power supply to charge the battery module. The first charge pulse calculation unit, the second charge pulse calculation unit, and the battery charge pulse calculation unit work to calculate the charge pulse at the next moment. The discharge control unit performs discharging based on a preset discharge policy, for example, discharging the fully charged cell to the ground GND, and 10% of a quantity of electricity is discharged; or based on a next battery close to a fully charged state, a quantity of electricity obtained after the fully charged cell is discharged is equal to a quantity of electricity of the next battery close to a fully charged state; or discharging the fully charged cell to a cell that reaches an undercharged state, so that the cell that reaches an undercharged state still does not reach a fully charged state after receiving electricity. For example, based on a cell having a smallest quantity of electricity, the fully charged cell uses half of a difference between a quantity of electricity of a fully charged cell and the smallest quantity of electricity as a required quantity of electricity for discharging, so that after the discharging, the quantities of electricity of the two cells are basically equal and neither reaches a fully charged state. For another example, based on a cell having a smallest quantity of electricity, the fully charged cell discharges 10% of a quantity of electricity of the fully charged cell to the cell having the smallest quantity of electricity. For another example, the fully charged cell evenly discharges 10% of a quantity of electricity of the fully charged cell to other undercharged cells.

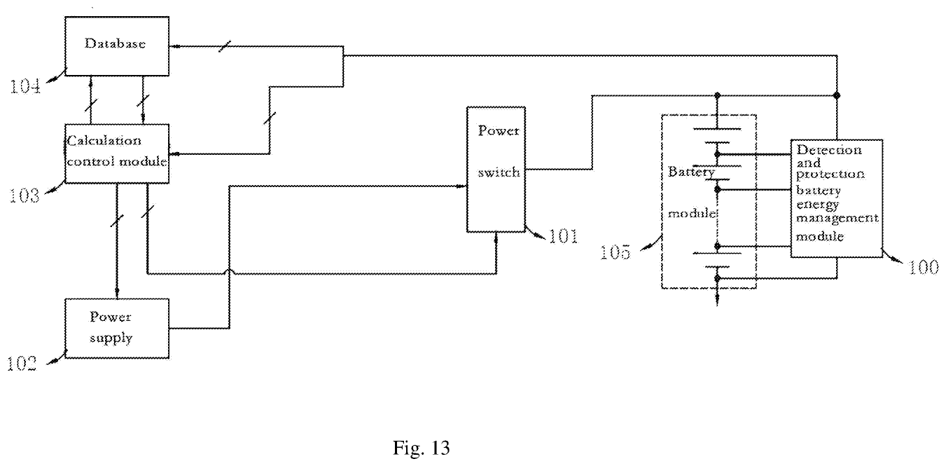

FIG. 13 shows a charge system of a battery with a plurality of serially connected cells. When the battery system has a plurality of serially connected cells, due to inevitable inconsistency among the cells, charge speeds of the cells are inconsistent during a charge, thereby causing an overcharge of some cells. A long-term uncontrolled overcharge of the cell can easily accelerate aging of the cell and even lead to thermal runaway. This case is more obvious when the battery is quickly charged. In an existing battery management system (such as passive or active management of lithium batteries), due to a limited balance capability between cells, both a conventional big current and quick charging causes imbalance between cells. The charge system used in FIG. 13 in the present invention can control an overcharge of each cell within a healthy range. The system includes a database 104, a calculation control module 103, a power supply 102, a power switch 101, a battery module 105, and a detection and protection battery energy management module 100. The module 100 integrates all functions of the detection and protection module and the battery energy management module, and is configured to: detect a current, a voltage, and temperature of each cell of the battery system in real time, protect the battery in an extreme case, perform simple balance between cells of the battery, and perform energy management between the cells of the battery. The power switch 101 and the power supply 102 are both controlled by the calculation control module 103, and are configured to control the power supply to charge the battery module 105. The database 104 includes a local area database and a cloud database.

First an initial battery parameter is entered in the database 104, such as an SOC of the battery, an SOH, internal resistance, and a curve of a change in t_{c1i}, t_{c2i}, tᵣ₁ᵢ, and tᵣ₂ᵢ of a cell of the battery varying with temperature, the SOC, and the SOH. The data tested by the detection and protection battery energy management module 100 is entered into the database in real time, and the calculation control module 103 corrects a curve of t_{c1}, t_{c2}, tᵣ₁, and tᵣ₂ of each cell at that moment, compares t_{c1i} and t_{c2i} of each cell, and calculates a minimum min{t_{c1l}, t_{c2i}} and a maximum max{tᵣ₁ₗ, tᵣ₂ᵢ}. According to min{t_{c1i}, t_{c2i}} and max{tᵣ₁ₗ, tᵣ₂ᵢ}, the calculation control module 103 generates a charge pulse by controlling the power supply 102 and the power switch 101, to charge the battery module 105. In addition, the detection and protection battery energy management module 100 continuously detects the cells and behavior in the battery module in real time, and generates a subsequent pulse sequence, until the battery is fully charged. When the charge current falls within a reasonable range, a pulse width is determined based on min{t_{ci1}}, and the relaxation time depends on max {tᵣᵢ₁}. Based on the method for charging the battery in a full life cycle in the present invention, the system can ensure that each cell works in a healthy area while safest and fastest charging is performed.

A person skilled in the art should understand that the embodiments of the present invention described above and shown in the accompanying drawings are merely examples and do not limit the present invention. The objective of the present invention has been completely and effectively achieved. The function and structural principle of the present invention have been shown and described in the embodiments, and the implementations of the present invention can be varied or modified without departing from the principle.

1. A method for charging a cell including pulse charging at an overcharge voltage or an overcharge current, comprising:
if a charge current is controlled within a safety range, and a second charge time t_{c2} is not less than a first charge time t_{c1}, charging the cell for a time that does not exceed the first charge time t_{c1}; and
if a charge voltage is controlled within a safety range, and the first charge time t_{c1} is not less than the second charge time t_{c2}, charging the cell for a time that does not exceed the second charge time t_{c2}, wherein the first charge time is a longest time within which the cell is at the overcharge voltage but no irreversible damage has been formed during a charge; the second charge time is a longest time within which the cell is at the overcharge current but no irreversible damage has been formed during a charge;
pulse charging the cell at the overcharge voltage for the time that does not exceed the first charge time t_{c1} and a charge current is controlled within a safety range, or pulse charging the cell at the overcharge current for the time that does not exceed the second charge time t_{c2}, and a charge voltage is controlled within a safety range;
wherein when the cell is charged for the time that does not exceed the first charge time t_{c1}, the cell recovers from an overcharged state where the overcharge voltage is applied to a normal state after the overcharge voltage is applied within a time not less than a first relaxation time tᵣ₁, the first relaxation time is a time within which the cell recovers from the overcharged state where the overcharge voltage is applied to the normal state after the overcharge voltage is applied after the first charge time; when the cell is charged for the time that does not exceed the second charge time t_{c2}, the cell recovers from the overcharged state where the overcharge voltage is applied to the normal state after the overcharge voltage is applied within a time not less than a second relaxation time tᵣ₂, the second relaxation time is a time within which the cell recovers from an overcharged state where the overcharge current is applied to a normal state after the second charge time after the overcharge current is applied.

2. The method for charging the cell including pulse charging at an overcharge voltage or an overcharge current according to claim 1, wherein the first charge time varies with ambient temperature, a charge current, a state of charge SOC, and a state of health SOH of a battery; a battery comprising the cell.

3. The method for charging the cell including pulse charging at an overcharge voltage or an overcharge current according to claim 1, wherein the first charge time is in inverse proportion of the overcharge voltage.

4. The method for charging the cell including pulse charging at an overcharge voltage or an overcharge current according to claim 1, wherein the second charge time varies with ambient temperature, the charge voltage, a state of charge SOC, and a state of health SOH of a battery.

5. The method for charging the cell including pulse charging at an overcharge voltage or an overcharge current according to claim 1, wherein the second charge time is in reverse proportion of the overcharge current.

6. (canceled)

7. (canceled)

8. A method for charging a battery in a full life cycle including pulse charging at an overcharge voltage or an overcharge current, a battery comprising a plurality cells, and the method comprising:
monitoring real-time data of the battery charged based on a charge pulse at a current moment;
calculating a charge pulse with the overcharge voltage or the overcharge current at a next moment based on the real-time data of the battery, changing information of a first charge time t_{c1} and a first relaxation time tᵣ₁, and changing information of a second charge time t_{c2} and a second relaxation time tᵣ₂, so that the battery has a longest time in a healthy state; during the longest time, the battery being at the overcharge voltage but no irreversible damage has been formed during a charge or at the overcharge current but no irreversible damage has been formed during a charge current; and
charging the battery at the overcharge voltage or at the overcharge current by using the calculated charge pulse, wherein the foregoing monitoring, calculating, and charging process is repeated before the battery is fully charged, wherein
the real-time data of the battery comprises voltage, current, and temperature data of the battery;
the first charge time is a longest time within which a cell is at the overcharge voltage but no irreversible damage has been formed during a charge; the first charge time varies with ambient temperature, a charge current, a state of charge SOC, and a state of health SOH of the battery; the first relaxation time is a time within which the cell recovers from an overcharged state where the overcharge voltage is applied to a normal state after the overcharge voltage is applied after the first charge time;
the second charge time is a longest time within which the cell is at the overcharge current but no irreversible damage has been formed during a charge; the second charge time varies with ambient, a charge voltage, a state of charge SOC, and a state of health SOH of the battery; the second relaxation time is a time within which the cell recovers from an overcharged state where the overcharge current is applied to a normal state after the overcharge current is applied after the second charge time; and
the charge pulse comprises the charge voltage, the first charge time, and the first relaxation time or the second relaxation time; or the charge pulse comprises the charge current, the second charge time, and the second relaxation time or the first relaxation time.

9. The method for charging the battery in a full life cycle including pulse charging at an overcharge voltage or an overcharge current according to claim 8, wherein a principle for selecting the longest time for charging the battery in a healthy state at the overcharge voltage but no irreversible damage has been formed during a charge or at the overcharge current but no irreversible damage has been formed during a charge is:
if the charge current is controlled within in a safety range, and the second charge time t_{c2} is not less than the first charge time t_{c1}, charging the cell for a time that does not exceed the first charge time t_{c1}; and
if the charge voltage is controlled within in a safety range, and the first charge time t_{c1} is not less than the second charge time t_{c2}, charging the cell for a time that does not exceed the second charge time t_{c2}.

10. The method for charging the battery in a full life cycle including pulse charging at an overcharge voltage or an overcharge current according to claim 8, wherein the step of calculating a charge pulse at a next moment based on the real-time data of the battery, changing information of a first charge time t_{c1} and a first relaxation time tᵣ₁, and changing information of a second charge time t_{c2} and a second relaxation time tᵣ₂, so that the battery has a longest time in a healthy state; during the longest time, the battery being at the overcharge voltage but no irreversible damage has been formed during a charge or at the overcharge current but no irreversible damage has been formed during a charge current comprises:
determining a first charge pulse of the cell at a next moment based on the real-time data of the battery and a first curve of a first charge time t_{c1} and a first relaxation time tᵣ₁ of the cell varying with a charge voltage, temperature, an SOC, and an SOH; repeating said step of determining the first charge pulse of the cell until the first charge pulse of the plurality of cells have been determined;
determining a second charge pulse of the cell at the next moment based on the real-time data of the battery and a second curve of a second charge time t_{c2} and a second relaxation time tᵣ₂ of the cell varying with a charge current, temperature, an SOC, and an SOH; repeating said step of determining the second charge pulse of the cell until the second charge pulse of the plurality of cells have been determined; and
selecting a smallest charge time from first charge time tc1 in first charge pulses and second charge time t_{c2} in second charge pulses of the plurality of cells, selecting a largest relaxation time from first relaxation time tᵣ₁ in the first charge pulses and second relaxation time tᵣ₂ in the second charge pulses of the plurality of cells, and constituting the charge pulse of the battery at the next moment by using the smallest charge time and the largest relaxation time that are selected.

11. The method for charging the battery in a full life cycle including pulse charging at an overcharge voltage or an overcharge current according to claim 10, wherein the method of calculating the charge pulse at the next moment is applicable to a battery formed by serially connecting a plurality of cells, or a battery formed by connecting a plurality of cells in parallel, or a battery formed by connecting a plurality of cells serially and in parallel.

12. The method for charging the battery in a full life cycle including pulse charging at an overcharge voltage or an overcharge current according to claim 8, wherein when the battery comprises serially connected cells, the step of calculating a charge pulse at a next moment based on the real-time data of the battery, changing information of a first charge time t_{c1} and a first relaxation time tᵣ₁, and changing information of a second charge time t_{c2} and a second relaxation time tᵣ₂, so that the battery has a longest time for being at a highest bearable charge voltage or charge current in a healthy state comprises:
when none of the serially connected cells are fully charged,
determining a first charge pulse of the cell at a next moment based on the real-time data of the battery and a first curve of a first charge time t_{c1} and a first relaxation time tᵣ₁ of the cell varying with a charge voltage, temperature, an SOC, and an SOH; repeating said step of determining the first charge pulse of the cell until the first charge pulse of the plurality of cells have been determined;
determining a second charge pulse of the cell at the next moment based on the real-time data of the battery and a second curve of a second charge time t_{c2} and a second relaxation time tᵣ₂ of the cell varying with a charge current, temperature, an SOC, and an SOH; repeating said step of determining the second charge pulse of the cell until the second charge pulse of the plurality of cells have been determined; and
selecting a smallest charge time from first charge time t_{c1} in first charge pulses and second charge time t_{c2} in second charge pulses of the plurality of cells, selecting a largest relaxation time from first relaxation time tᵣ₁ in the first charge pulses and second relaxation time tᵣ₂ in the second charge pulses of the plurality of cells, and constituting the charge pulse of the battery at the next moment by using the smallest charge time and the largest relaxation time that are selected; and
when at least one of the serially connected cells reaches a fully charged state,
first discharging the cell in a fully charged state;
then determining a first charge pulse of the cell at a next moment based on the real-time data of the battery and a first curve of a first charge time t_{c1} and a first relaxation time tᵣ₁ of the cell varying with a charge voltage, temperature, an SOC, and an SOH;
determining a second charge pulse of the cell at the next moment based on the real-time data of the battery and a second curve of a second charge time t_{c2} and a second relaxation time tᵣ₂ of the cell varying with a charge current, temperature, an SOC, and an SOH; and
selecting a smallest charge time from first charge time t_{c1} in first charge pulses and second charge time t_{c2} in second charge pulses of the plurality of cells, selecting a largest relaxation time from first relaxation time tᵣ₁ in the first charge pulses and second relaxation time tᵣ₂ in the second charge pulses of the plurality of cells, and constituting the charge pulse of the battery at the next moment by using the smallest charge time and the largest relaxation time that are selected.

13. The method for charging the battery in a full life cycle including pulse charging at an overcharge voltage or an overcharge current according to claim 12, wherein a manner of discharging the cell in a fully charged state comprises:
discharging the fully charged cell to the ground; or
discharging the fully charged cell to a cell that reaches an undercharged state, so that the cell that reaches an undercharged state still does not reach a fully charged state after charging.

14. The method for charging the battery in a full life cycle including pulse charging at an overcharge voltage or an overcharge current according to claim 10, further comprising: correcting the first curve and the second curve of the cell in real time based on the real-time data of the battery, the SOC, and the SOH.

15. The method for charging the battery in a full life cycle including pulse charging at an overcharge voltage or an overcharge current according to claim 8, wherein the method is applicable to a charge of a chemical battery.

16. A system for charging the battery in a full life cycle including pulse charging at an overcharge voltage or an overcharge current, comprising a battery module, a detection and protection module, a power supply, a database, and a calculation control module, wherein the database stores changing information of a first charge time t_{c1} and a first relaxation time tᵣ₁ of the battery, and changing information of a second charge time t_{c2} and a second relaxation time tᵣ₂; the detection and protection module is configured to detect the battery module in real time, to obtain real-time data of the battery in the battery module; the calculation control module calculates a charge pulse with the overcharge voltage or with the overcharge current at a next moment based on the real-time data of the battery, the changing information of the first charge time t_{c1} and the first relaxation time tᵣ₁, and the changing information of the second charge time t_{c2} and the second relaxation time tᵣ₂, so that the battery has a longest time in a healthy state; during the longest time, the battery being at the overcharge voltage but no irreversible damage has been formed during a charge or at the overcharge current but no irreversible damage has been formed during a charge current; and the power supply performs charging at the overcharge voltage or at the overcharge current based on the charge pulse calculated by the calculation control module, until charging is completed;
the real-time data of the battery comprises voltage, current, and temperature data of the battery.
the first charge time is a longest time within which a cell is at an overcharge voltage but no irreversible damage has been formed during a charge; the first charge time varies with ambient temperature, a charge current, a state of charge SOC, and a state of health SOH of the battery; the first relaxation time is a time within which the cell recovers from an overcharged state where the overcharge voltage is applied to a normal state after the overcharge voltage is applied after the first charge time;
the second charge time is a longest time within which the cell is at an overcharge current but no irreversible damage has been formed during a charge; the second charge time varies with environment temperature, a charge voltage, a state of charge SOC, and a state of health SOH of the battery; the second relaxation time is a time within which the cell recovers from an overcharged state where the overcharge current is applied to a normal state after the overcharge current is applied after the second charge time; and
the charge pulse comprises the charge voltage, the first charge time, and the first relaxation time or the second relaxation time; or the charge pulse comprises the charge current, the second charge time, and the second relaxation time or the first relaxation time.

17. The system for charging the battery in a full life cycle including pulse charging at an overcharge voltage or an overcharge current according to claim 16, wherein the calculation control module comprises:
a first charge pulse calculation unit, configured to determine a first charge pulse of the cell at a next moment based on the real-time data of the battery and a first curve of a first charge time t_{c1} and a first relaxation time tᵣ₁ of the cell varying with a charge voltage, temperature, an SOC, and an SOH, and configured to determine the first charge pulse of the plurality of cells by repeating said step of determining the first charge pulse of the cell;
a second charge pulse calculation unit, configured to determine a second charge pulse of the cell at the next moment based on the real-time data of the battery and a second curve of a second charge time t_{c2} and a second relaxation time tᵣ₂ of the cell varying with a charge current, temperature, an SOC, and an SOH, and configured to determine the second charge pulse of the plurality of cells by repeating said step of determining the second charge pulse of the cell; and
a battery charge pulse calculation unit, configured to: select a smallest charge time from first charge time t_{c1} in first charge pulses and second charge time t_{c2} in second charge pulses of the plurality of cells, select a largest relaxation time from first relaxation time tᵣ₁ in the first charge pulses and second relaxation time tᵣ₂ in the second charge pulses of the plurality of cells, and constitute the charge pulse of the battery at the next moment by using the smallest charge time and the largest relaxation time that are selected.

18. The system for charging the battery in a full life cycle including pulse charging at an overcharge voltage or an overcharge current according to claim 17, further comprising a battery energy management module and a switch module that are disposed between the power supply and the battery module; the calculation control module further comprises a discharge control unit, configured to: when the battery energy management module detects that at least one of serially connected cells reaches a fully charged state, control the switch module to cut off from the power supply and control the cell reaching a fully charged state to perform a discharge operation; and after the discharge is completed, then control the switch module to connect to the power supply for charging, and trigger the first charge pulse calculation unit, the second charge pulse calculation unit, and the battery charge pulse calculation unit to work.
